(19) United States
(12) Patent Application Publication
(10) Pub. No.: US 2023/0120885 A1
(43) Pub. Date: Apr. 20, 2023

(54) THREE-DIMENSIONAL MEMORY AND FORMING METHOD THEREOF

(71) Applicant: YANGTZE MEMORY TECHNOLOGIES CO., LTD., Wuhan (CN)

(72) Inventor: Linchun WU, Wuhan (CN)

(21) Appl. No.: 18/082,486

(22) Filed: Dec. 15, 2022

Related U.S. Application Data
(63) Continuation of application No. PCT/CN2021/125222, filed on Oct. 21, 2021.

(30) Foreign Application Priority Data
Oct. 21, 2020 (CN) 202011134486.X

(51) Int. Cl. H10B 43/27; H10B 41/27

(52) U.S. Cl. CPC H01L 27/11582; H01L 27/11556

(57) ABSTRACT

Embodiments of the present disclosure provide a three-dimensional memory and a forming method thereof. The method includes: providing a base structure; forming a first channel hole in the base structure; forming a third protective layer on a side wall of the first sacrificial layer; forming a second sacrificial layer in the first channel hole; forming a first stacked structure; forming a second channel hole in the first stacked structure, the second channel hole penetrating the first stacked structure vertically, and an orthographic projection of the second channel hole onto the bottom dielectric layer being located within the first channel hole; removing the second sacrificial layer; forming a channel structure in the first channel hole and the second channel hole, the channel structure including a channel layer and a storage stacked layer surrounding an outer side surface and an outer bottom surface of the channel layer.

### CROSS-REFERENCE TO RELATED APPLICATION

This application is a continuation of International Application No. PCT/CN2021/125222, filed on Oct. 21, 2021, which claims the benefit of priority to Chinese Application No. 202011134486.X, filed on Oct. 21, 2020, the entire contents of which are incorporated herein by reference in their entireties.

### TECHNICAL FIELD

The present disclosure relates to the technical field of semiconductor integrated circuits, and in particular, relates to a three-dimensional memory and a forming method of the three-dimensional memory.

### BACKGROUND

With side Wail Polysilicon (SWP) structures, the challenges in etching silicon-oxide-nitride-oxide (SONO) of three-dimensional (3D) NAND caused by an increasing number of layers can be avoided. However, with the removal of a bottom polysilicon sacrificial layer (SAC poly) and oxide-nitride-oxide (ONO), the support of a core region and a dummy region will face great challenges due to a small channel aperture. Furthermore, when the number of layers of a storage structure is relatively high, the bottom of a channel hole tends to be deformed in the formation of the channel hole, resulting in deteriorated uniformity under the channel holes (uneven spacing between the channel holes), thereby affecting a filling process window after the polysilicon sacrificial layer is removed.

### SUMMARY

According to a first aspect of an embodiment of the present disclosure, there is provided a method for forming a three-dimensional memory, including steps of:
providing a base structure including a first protective layer, a first sacrificial layer, a second protective layer, and a bottom dielectric layer sequentially from bottom to top;
forming a first channel hole in the base structure, the first channel hole penetrating vertically through the bottom dielectric layer, the second protective layer, the first sacrificial layer, and the first protective layer;
forming a third protective layer on a side wall, which is exposed by the first channel hole of the first sacrificial layer;
forming a second sacrificial layer in the first channel hole;
forming a first stacked structure on the bottom dielectric layer, the first stacked structure including gate sacrificial layers and dielectric layers, the gate sacrificial layers and dielectric layers are alternately stacked;
forming a second channel hole in the first stacked structure, the second channel hole penetrating vertically through the first stacked structure, and an orthographic projection of the second channel hole onto the bottom dielectric layer being located within the first channel hole;
removing the second sacrificial layer; and
forming a channel structure in the first channel hole and the second channel hole, the channel structure including a channel layer and a storage stacked layer surrounding an outer side surface and an outer bottom surface of the channel layer; wherein a size of a bottom of the channel structure along a horizontal direction is greater than a size of a portion, which is located in the first stacked structure of the channel structure.

In some embodiments, after forming the second channel hole and before removing the second sacrificial layer, the method further includes steps:
forming a third sacrificial layer in the second channel hole;
forming a second stacked structure on the first stacked structure, the second stacked structure including gate sacrificial layers and dielectric layers, the gate sacrificial layers and dielectric layers are alternately stacked;
forming a third channel hole in the second stacked structure, the third channel hole penetrating vertically through the second stacked structure, and an orthographic projection of the third channel hole onto the first stacked structure being located within the second channel hole;
removing the third sacrificial layer; and
when forming the channel structure after removing the third sacrificial layer and the second sacrificial layer, forming the channel structure also in the third channel hole.

In some embodiments, the method further includes steps of:
forming a gate line slit, the gate line slit penetrating vertically through the first stacked structure and extending at least down into the first sacrificial layer;
forming a side wall protective layer on a side wall of the gate line slit;
removing the first sacrificial layer to obtain a bottom lateral slit;
removing a portion of the storage stacked layer via the bottom lateral slit to expose a portion of the channel layer and removing the first protective layer and the second protective layer;
forming a bottom polysilicon layer in the bottom lateral slit;
removing the gate sacrificial layer to obtain a plurality of gate lateral slits;
firming a conductive layer in the gate lateral slits; and
forming an array common source structure in the gate line slit.

In some embodiments, the base structure includes a substrate. The first protective layer is located between the substrate and the first sacrificial layer. A groove is provided in the substrate before forming the first channel hole. The groove is filled with the first protective layer and the first sacrificial layer. An orthographic projection of the gate line slit onto the substrate is located within the groove.

In some embodiments, after forming the bottom polysilicon layer and before removing the gate sacrificial layer, the method further includes a step of forming a bottom epitaxial layer in the groove.

In some embodiments, the bottom epitaxial layer includes an N-type epitaxial silicon layer and an N-type polysilicon layer sequentially from bottom to top.

In some embodiments, the three-dimensional memory includes a step region. The method further includes a step of forming an annular groove in the step region before forming the first stacked structure, the annular groove penetrating vertically through the first sacrificial layer and the first protective layer. In the step of forming the third protective layer, the third protective layer is further formed on a side wall, which is exposed by the annular groove, of the first sacrificial layer. In the step of forming the second sacrificial layer in the first channel hole, the second sacrificial layer is further formed in the annular groove. In the step of removing the first sacrificial layer to obtain the bottom lateral slit, a portion of the first sacrificial layer surrounded by the annular groove is not removed.

In some embodiments, the annular groove is in a shape of a polygonal ring, a circular ring, or an elliptical ring.

In some embodiments, the method further includes a step of forming a plurality of dummy channel holes in the step region.

In some embodiments, at least one of the dummy channel holes is located within a surrounding area of the annular groove; and/or at least one of the dummy channel holes is located outside the surrounding area of said annular groove.

According to a second aspect of an embodiment of the present disclosure, there is provided a three-dimensional memory, including:
a bottom polysilicon layer;
a bottom dielectric layer on the bottom polysilicon layer;
a plurality of conductive layers stacked above the bottom dielectric layer, a dielectric layer being disposed between adjacent conductive layers;
a channel structure penetrating vertically through the plurality of conductive layers and the dielectric layer and extending down into the bottom polysilicon layer, the channel structure including a channel layer and a storage stacked layer surrounding an outer side surface and an outer bottom surface of the channel layer, the bottom polysilicon layer extending laterally through the storage stacked layer to be connected to the channel layer, where a size of a bottom of the channel structure in a horizontal direction is greater than a size of a portion of the channel structure in the conductive layer.

In some embodiments, the bottom of the channel structure includes:
a portion of the channel structure located in the bottom dielectric layer; and
a portion of the channel structure in the substrate; wherein the bottom polysilicon layer is located between the substrate and the bottom dielectric layer.

In some embodiments, a portion of the channel structure in the plurality of conductive layers and the dielectric layer is divided into at least two segments, wherein a width of an upper segment of the channel structure is less than a width of a lower segment of the channel structure.

In some embodiments, the three-dimensional memory includes:
a substrate; wherein the bottom polysilicon layer is located between the substrate and the bottom dielectric layer; and
a step region provided with an annular groove structure, the annular groove structure penetrating vertically through the bottom polysilicon layer and extending down into the substrate.

In some embodiments, the annular groove structure is in a shape of a polygonal ring, a circular ring, or an elliptical ring.

In some embodiments. the step region is provided with a plurality of dummy channel hole structures.

In some embodiments, at least one of the dummy channel hole structures is located within a surrounding area of the annular channel structure; and/or at least one of the dummy channel hole structures is located outside the surrounding area of the annular groove structure.

According to a third aspect of an embodiment of the present disclosure, there is provided another three-dimensional memory, including:
a bottom polysilicon layer;
a bottom dielectric layer on the bottom polysilicon layer;
a plurality of conductive layers stacked above the bottom dielectric layer, a dielectric layer being disposed between adjacent conductive layers; and
a channel structure penetrating vertically through the conductive layers and the dielectric layer and extending down into the bottom polysilicon layer, the channel structure including a channel layer and a storage stacked layer surrounding an outer side surface and an outer bottom surface of the channel layer, the bottom polysilicon layer penetrating laterally through the storage stacked layer to be connected to the channel layer, where the channel structure includes a protruding portion at a bottom in a direction in which the bottom polysilicon layer extends.

In some embodiments, the channel structure includes a protruding portion at a bottom in a direction in which the bottom polysilicon layer extends includes: the protruding portion is located in the bottom dielectric layer, the bottom polysilicon layer, and a substrate; wherein the bottom polysilicon layer is located between the substrate and the bottom dielectric layer.

In some embodiments, a portion of the channel structure in the plurality of conductive layers and the dielectric layer is divided into at least two segments, wherein a width of an upper segment of the channel structure is less than a width of a lower segment of the channel structure.

In some embodiments, the three-dimensional memory includes:
a substrate; wherein the bottom polysilicon layer is located between the substrate and the bottom dielectric layer; and
a step region provided with an annular groove structure, the annular groove structure penetrating vertically through the bottom polysilicon layer and extending down into the substrate.

In some embodiments, the step region is provided with a plurality of dummy channel hole structures.

In some embodiments, at least one of the dummy channel hole structures is located within a surrounding area of the annular channel structure; and/or at least one of the dummy channel hole structures is located outside the surrounding area of the annular groove structure.

In some embodiments, the three-dimensional memory further includes an array common source structure, the array common source structure penetrating vertically through the plurality of conductive layers, the plurality of dielectric layers, and the bottom dielectric layer.

According to the three-dimensional memory of the embodiments of the present disclosure and the forming method thereof, a lower part of the channel hole is formed by etching the bottom of the channel hole at a position of the channel hole, and an upper part of the channel hole is formed by oxidizing the side wall of the first sacrificial laser, filling the hole with the second sacrificial layer and then forming a stacked structure. On one hand, the lower part of the channel hole having a larger size may improve the supporting capability of a core region and a dummy region after the removal of the bottom sacrificial layer. On the other hand, the lower part of the channel hole having a larger size may reduce the deformation of the bottom of the channel hole in the core region, and make the distribution of the holes more uniform, which is conducive to improving a filling process window after the removal of the bottom sacrificial layer, and may directly form a silicon gouging with a relatively deep bottom, so as to avoid a key dimension enlargement of the top of the channel hole during the formation of the silicon gouging after the etching. In addition, the dummy region may be further an annular groove when the bottom is etched, which prevents an intermediate region surrounded by the annular groove from being removed when the bottom sacrificial layer is removed, thereby greatly improving the support capacity of the core region and the dummy region when the bottom sacrificial layer is removed.

### BRIEF DESCRIPTION OF THE DRAWINGS

In order to better explain embodiments of the present disclosure or the technical solutions in the related art, the accompanying drawings are described below. The accompanying drawings in the following description are some embodiments of the present disclosure, and other drawings may be conceived from these drawings without creative effort by those ordinary skilled in the art.

FIG. 1 illustrates a process flow chart illustrating a method for forming a three-dimensional memory according to the present disclosure.

FIG. 2 is a schematic diagram illustrating a base structure.

FIG. 3 is a schematic diagram illustrating forming a first channel hole in a base structure.

FIG. 4 is a schematic diagram illustrating forming a third protective layer on a side wall, which is exposed by the first channel hole, of the first sacrificial layer.

FIG. 5 is a schematic diagram illustrating forming a second sacrificial layer in the first channel hole.

FIG. 6 illustrates a schematic diagram illustrating removing the second sacrificial layer on the bottom dielectric layer.

FIG. 7 is a schematic diagram illustrating forming a first stacked structure on the bottom dielectric layer.

FIG 8 is a schematic diagram illustrating forming a second channel hole in the first stacked structure.

FIG. 9 is a schematic diagram illustrating a post-etching treatment process of the structure illustrated in FIG. 8.

FIG. 10 is a schematic diagram illustrating forming a third sacrificial layer in the second channel hole.

FIG. 11 is a schematic diagram illustrating removing a third sacrificial layer on the first stacked structure.

FIG. 12 is a schematic diagram illustrating forming a second stacked structure on the first stacked structure.

FIG. 13 is a schematic diagram illustrating forming a third channel hole in the second stacked structure.

FIG. 14 is a schematic diagram illustrating forming a polysilicon liner layer on a side wall surface of the third channel hole.

FIG. 15 is a schematic diagram illustrating a post-etching treatment of the structure illustrated in FIG. 14.

FIG. 16 illustrates a schematic diagram illustrating removing the second and third sacrificial layers.

FIG. 17 is a schematic diagram illustrating forming a channel structure in the first channel hole, the second channel hole, and the third channel hole.

FIG. 18 is a schematic diagram illustrating further depositing a cover layer on the stacked structure to cover the channel structure.

FIG. 19 is a schematic diagram illustrating depositing a side wall protective layer within the gate line slit and on the stacked structure.

FIG. 20 is a schematic diagram illustrating removing a portion of the side wall protective layer at the bottom of the gate line slit to expose at least a portion of the first sacrificial layer, and removing a portion of the side wall protective layer on the stacked structure.

FIG. 21 is a schematic diagram illustrating removing the first sacrificial layer to obtain a bottom lateral slit.

FIG. 22 is a schematic diagram illustrating removing a barrier layer in a storage stacked layer along a side wall of the bottom lateral slit.

FIG. 23 is a schematic diagram illustrating removing an aluminum oxide layer from the side wall protective layer.

FIG. 24 is a schematic diagram illustrating removing a storage layer and a tunneling layer in an exposed storage stacked layer.

FIG. 25 is a schematic diagram illustrating pre-cleaning a surface of the bottom lateral slit.

FIG. 26 is a schematic diagram illustrating depositing a bottom polysilicon layer in the bottom lateral slit.

FIG. 27 is a schematic diagram illustrating removing polysilicon material on a side wall of the gate line slit and on the cover layer through etchback.

FIG. 28 is a schematic diagram illustrating continuing to form a bottom epitaxial layer in a groove.

FIG. 29 is a schematic diagram illustrating further removing a silicon oxide layer on the side wall protective layer.

FIG. 30 is a schematic diagram illustrating removing a gate sacrificial layer to obtain a plurality of gate lateral slits.

FIG. 31 is a schematic diagram illustrating forming a conductive layer in a gate lateral slit.

FIG. 32 is a schematic diagram illustrating forming an isolated side wall on the side wall of the gate line slit.

FIG. 33 is a schematic diagram illustrating removing a portion of the isolated side wall on the cover layer and removing a portion of the isolated side wall and the alumina layer on the middle of the bottom of the gate line slit 23.

FIG. 34 illustrates forming a conductive portion of an array common source structure.

FIG. 35 illustrates a plane layout of a three-dimensional memory.

FIG. 36 is a cross-sectional diagram of the three-dimensional memory along the A-A′ direction.

### Reference Numerals

S1˜S8—step; 1—substrate; 2—first protective player; 3—first sacrificial layer; 4—second protective layer; 5—bottom dielectric layer; 6—groove; 7—first channel hole; 8—third protective layer; 9—second sacrificial layer; 10—gate sacrificial layer; 11—dielectric layer; 12—second channel hole; 13—third sacrificial layer; 14—third channel hole; 15—polysilicon liner layer; 16—channel layer; 17—barrier layer; 18—storage layer; 19—tunneling layer; 20—filling material; 21—semiconductor contact part; 22—cover layer; 23—gate line slit; 24—first silicon nitride layer; 25—silicon oxide layer; 26—second silicon nitride layer; 27—aluminum oxide layer; 28—bottom lateral slit; 29—bottom polysilicon layer; 30—N-type epitaxial silicon layer; 31—N-type polysilicon layer; 32—gate lateral slit; 33—gate material layer; 34—aluminum oxide layer; 35—titanium nitride layer; 36—isolated wall; 37—titanium nitride layer; 38—dielectric layer; 39—tungsten layer; 40—annular groove; 41—dummy channel hole; I—core region; II—step region.

### DETAILED DESCRIPTION

The following embodiments are provided for a better understanding of the present disclosure, and the content and scope of protection of the present disclosure are not limited. Any product the same as or similar to the present disclosure, which is made by anyone under the teaching of the present disclosure or through combining the present disclosure with other related art features, falls within the scope of protection of the present disclosure.

In the present disclosure, it is to be noted that the terms for indicating an orientation or a position relation such as “on,” “under,” “inside” and “outside” is based on an orientation or a position relation illustrated in figures, and are merely for the convenience of description of the present disclosure and for simplifying the description. Such terms do not indicate or suggest that a corresponding device or element must have a specific orientation, or is constructed or operated in the specific orientation, and shall not be considered to limit the present disclosure. In addition, the terms such as “first,” “second” and so on are merely for the purpose of description, and shall not be considered to indicate or suggest relative significance.

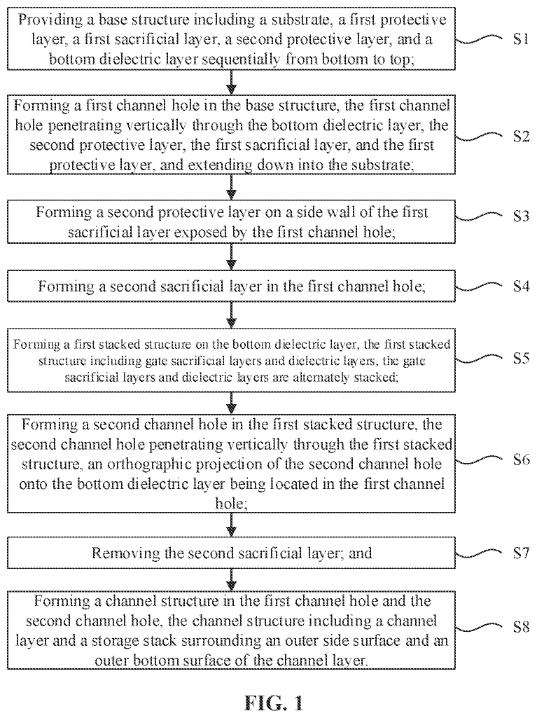

Refer to FIGS. 1 to 36. It is to be noted that the drawings provided in the present embodiment only illustrate the basic concept of the present disclosure in a schematic manner, and thus the drawings only show components related to the present disclosure instead of being plotted according to the number, shape, and size of the components when implemented. The pattern, number, and proportion of the components may be arbitrarily changed when actually implemented, and the layout of the components may be more complicated.

### First Embodiment

An embodiment of the present disclosure provides a method for forming a three-dimensional memory. Referring to FIG. 1, a process flow chart illustrating the method is shown, and the flow chart includes the following steps S1-S6.

In S1, a base structure is provided. The base structure includes a substrate, a first protective layer, a first sacrificial layer, a second protective layer, and a bottom dielectric layer sequentially from bottom to top.

In S2, a first channel hole is formed in the base structure. The first channel hole penetrates vertically through the bottom dielectric layer, the second protective layer, the first sacrificial layer, and the first protective layer, and extends down into the substrate.

In S3, a third protective layer is formed on a side wall, which is exposed by the first channel hole, of the first sacrificial layer.

In S4, a second sacrificial layer is formed in the first channel hole,

In S5, a first stacked structure is formed on the bottom dielectric layer. The first stacked structure includes gate sacrificial layers and dielectric layers, the gate sacrificial layers and dielectric layers are alternately stacked.

In S6, a second channel hole is formed in the first stacked structure. The second channel hole penetrates vertically through the first stacked structure, and an orthographic projection of the second channel hole onto the bottom dielectric layer is located within the first channel hole.

In S7, the second sacrificial layer is removed.

In S8, a channel structure is formed in the first channel hole and the second channel hole. The channel structure includes a channel layer and a storage stacked layer surrounding an outer side surface and an outer bottom surface of the channel layer.

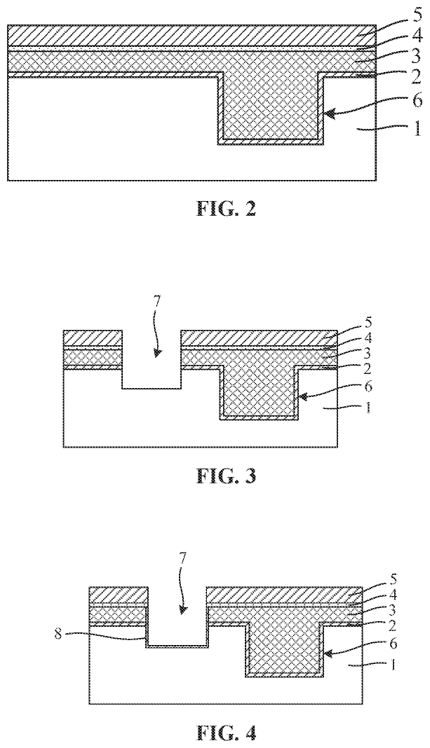

First, referring to FIG. 2, step S1 may be performed to provide a base structure including a substrate 1, a first protective layer 2, a first sacrificial layer 3, a second protective layer 4, and a bottom dielectric layer 5 sequentially from bottom to top.

For example, the substrate 1 may include, but is not limited to, a Silicon substrate, a Ge substrate, a Silicon substrate, a Silicon On Insulator (SOI) substrate, a Germanium On Insulator (GOI) substrate, or the like. The substrate 1 may be P-type doped or N-type doped. The first protective layer 2 may be used to protect a surface of the substrate 1. The first protective layer 2 may include, but is not limited to, a silicon oxide layer. The first sacrificial layer 3 may include, but is not limited to, a polysilicon layer. The second protective layer 4 may be used to protect the bottom dielectric layer 5. The second protective layer 4 may include, but is not limited to, a silicon nitride layer. The bottom dielectric layer 5 may include, but is not limited to, a silicon oxide layer.

For example, in order to enlarge a process window for subsequently forming a gate line slit, the substrate may be provided with a groove 6, and the groove is filled with the first protective layer 2 and the first sacrificial layer 3. An orthographic projection of the subsequently formed gate line slit onto the substrate 1 may be located within the groove 6.

Referring to FIG. 3, step S2 is performed to form a first channel hole 7 in the base structure. The first channel hole 7 may penetrate vertically through the bottom dielectric layer 5, the second protective layer 4, the first sacrificial layer 3, and the first protective layer 2, and extend down into the substrate 1.

For example, the first channel hole 7 may be formed through one or more wet etching and/or dry etching processes, such as Deep Reactive Ion Etching (DRIE).

In some embodiments, the first channel hole 7 may serve as a lower part of the entire channel hole and may be larger in size than an upper part of the entire channel hole formed subsequently. In this step, the lower part of the channel hole having a larger size may be formed first. On one hand, the supporting capacity of a core region and a dummy region after the removal of the bottom sacrificial layer may be improved. On the other hand, since a depth of the first channel hole 7 is far less than a depth of the entire channel hole, compared to directly forming a quite deep channel hole, the operation herein may achieve higher photolithographic accuracy and higher etch accuracy, which may reduce deformation of a bottom of the channel hole in the core region and make a distribution of the holes more uniform, thereby improving a filling process window. In addition, a silicon gouging having a deeper bottom, that is, the groove 6, may be formed so as to avoid a key dimension enlargement of the top of the channel hole during the formation of the silicon gouging after the channel hole is etched.

Referring to FIG. 4, step S3 may be performed to form a third protective layer 8 on a side wall of the first sacrificial layer 3 exposed by the first channel hole 7.

For example, the third protective layer 8 may be formed using a thermal oxidation method. The third protective layer 8 may include a silicon oxide layer. The third protective layer 8 may be used to protect the side wall of the first sacrificial layer 3 exposed by the first channel hole 7.

Referring to FIGS. 5 and 6, step S4 may be performed to form a second sacrificial layer 9 in the first channel hole 7.

For example, as illustrated in FIG. 5, the second sacrificial layer 9 may be formed in the first channel hole 7 by using at least one of chemical vapor deposition (CVD), physical vapor deposition (PVD), or atomic layer deposition (ALD). Then, as illustrated in FIG. 6, the second sacrificial layer 9 on the bottom dielectric layer 5 may be removed by using a chemical mechanical polishing method. The second sacrificial layer 9 may include, but is not limited to, a polysilicon layer.

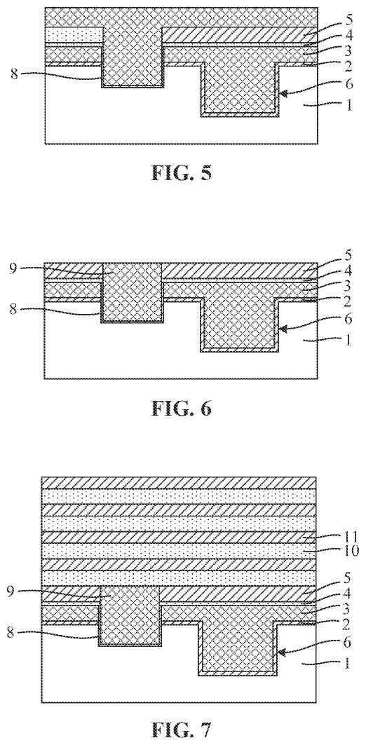

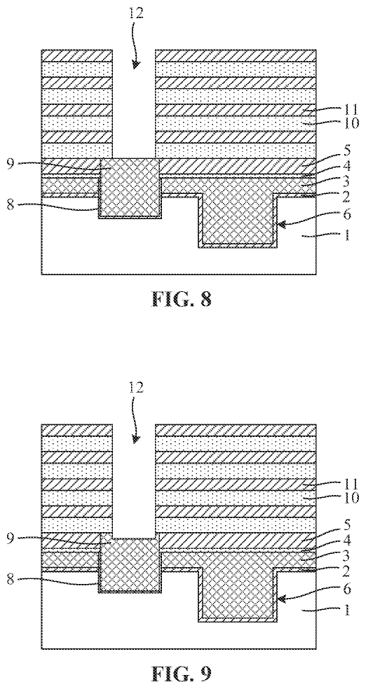

Referring to FIG. 7, step S5 may be performed to form a first stacked structure on the bottom dielectric layer 5. The first stacked structure includes gate sacrificial layers 10 and dielectric layers 11 that are alternately stacked.

For example, the gate sacrificial layer 10 and the dielectric layer 11 may be formed by using at least one of chemical vapor deposition (CVD), physical vapor deposition (PVD), or atomic layer deposition (ALD). The gate sacrificial layer 10 may include, but is not limited to, a silicon nitride layer. The dielectric layer 11 may include, but is not limited to, a silicon oxide layer

Also referring to FIG. 8, step S6 may be performed to form a second channel hole 12 in the first stacked structure. The second channel hole 12 may penetrate vertically through the first stacked structure. An orthographic projection of the second channel hole 12 onto the bottom dielectric layer 5 may be located within the first channel hole 7.

For example, the second channel hole 12 may be formed through one or more wet etching and/or dry etching processes, such as DRIE.

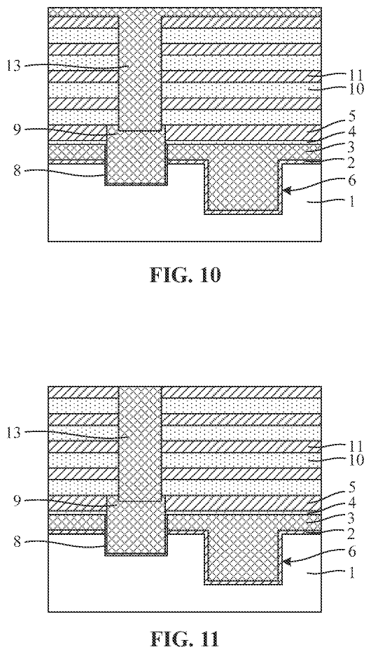

In this embodiment, as illustrated in FIG. 9, the method may further include a step of performing a post-etching treatment (PET).

It is to be noted that, if the remaining portion of the entire channel hole except the depth of the first channel hole 7 is less difficult to manufacture in one step, a subsequent step S7 may be continued. That is, the entire channel hole may be manufactured in two steps, and the entire channel hole may be composed of the first channel hole 7 and the second channel hole 12. If the remaining portion of the entire channel hole except the depth of the first channel hole 7 is difficult to manufacture in one step, the remaining portion of the entire channel hole may be manufactured in at least two steps. That is, the entire channel hole may be manufactured in three steps. The entire channel hole is formed by combining the first channel hole 7, the second channel hole 12 and a subsequently formed third channel hole or even more channel holes. Taking the entire channel hole as an example, after forming the second channel hole 12, the following steps may be continued.

(1) As illustrated in FIG. 10, the third sacrificial layer 13 may be formed in the second channel hole 12 by at least one of chemical vapor deposition (CVD), physical vapor deposition (PVD), or atomic layer deposition (ALD). As illustrated in FIG. 11, the third sacrificial layer 13 on the first stacked structure may be removed by chemical mechanical polishing. The third sacrificial layer 13 may include, but is not limited to, a polysilicon layer.

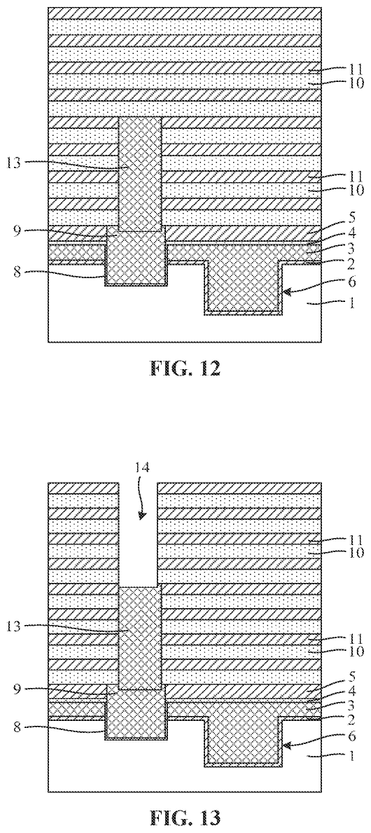

(2) As illustrated in FIG. 12, a second stacked structure may be formed on the first stacked structure in substantially the same manner as that of forming the first stacked structure. The second stacked structure may include gate sacrificial layers 10 and dielectric layers 11 that are alternately stacked.

(3) As illustrated in FIG. 13, a third channel hole 14 may be formed in the second stacked structure by one or more wet etching and/or dry etching processes, such as DRIE. The third channel hole 14 may penetrate vertically through the second stacked structure. An orthographic projection of the third channel hole 14 onto the first stacked structure may be located within the second channel hole 12.

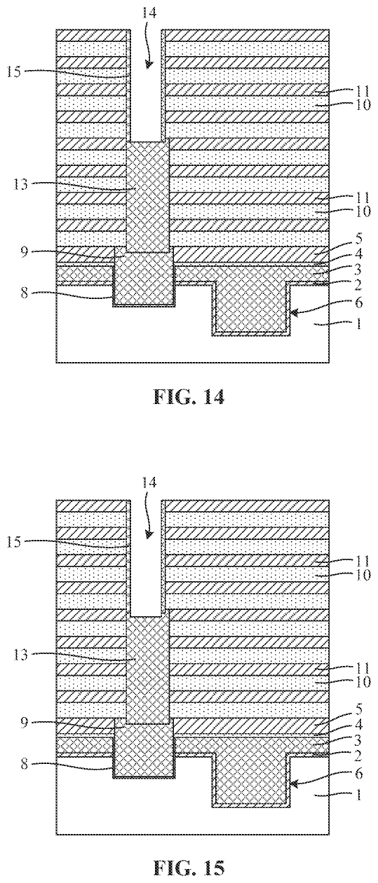

In this embodiment, as illustrated in FIG. 14, a polysilicon liner layer 15 may further be formed on a side wall surface of the third channel hole 14 to protect the side wall of the third channel hole 14. As illustrated in FIG. 15, a post-etching treatment process may be performed.

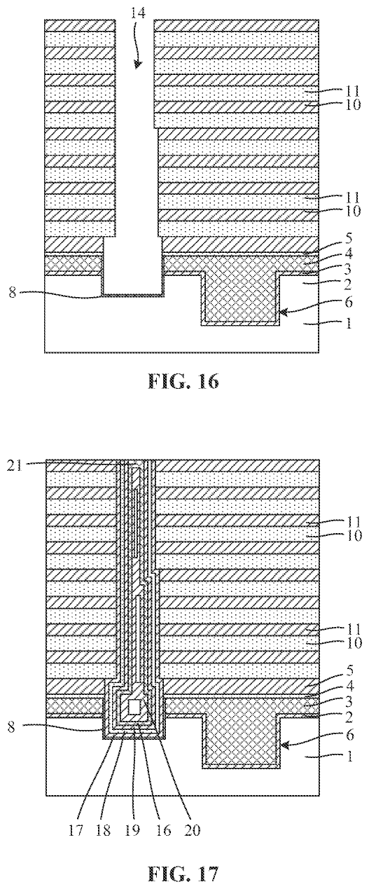

(4) As illustrated in FIG. 16, the third sacrificial layer 13 may be removed by using a wet etching process and/or a dry etching process.

It is to be noted that, in an ideal scenario, the first channel hole 7, the second channel hole 12, and the third channel hole 14 may be coaxial. However, due to practical process limitations, the central axes of the first channel hole 7, the second channel hole 12, and the third channel hole 14 may not coincide, and the protection scope of the present disclosure should not be excessively limited thereto.

For example, an aperture of the first channel hole 7 may be larger than an aperture of the second channel hole 12, and the aperture of the second channel hole 12 may be larger than an aperture of the third channel hole 14.

Referring to FIG. 16, step S7 may be performed to remove the second sacrificial layer 9 by using a wet etching process and/or a dry etching process.

In some embodiments, as described above, if the entire channel hole is manufactured in two steps, the second sacrificial layer 9 may be separately removed. If the entire channel hole is manufactured in three steps, the second sacrificial layer 9 may be removed together with the third sacrificial layer 13 during the removal of the third sacrificial layer 13.

In some embodiments, in the process of removing the second sacrificial layer 9 and/or the third sacrificial layer 13, the polysilicon liner layer 15 may be removed.

Referring to FIG. 17, step S8 may be performed to form a channel structure in the first channel hole 7 and the second channel hole 12. The channel structure may include a channel layer 16 and a storage stacked layer surrounding an outer side surface and an outer bottom surface of the channel layer 16.

In this embodiment, the channel structure may further be formed in the third channel hole 14.

In some embodiments, forming a vertical channel structure includes the following steps.

In step S8-1, at least one of chemical vapor deposition (CVD), physical vapor deposition (PVD), or atomic layer deposition (ALD) may be used to form the storage stacked layer on a side wall and a bottom surface of the channel hole. The storage stacked layer may include a barrier layer 17, a storage layer 18, and a tunneling layer 19 sequentially from outside to inside in a radial direction of the channel hole. The barrier layer 17 may include, but is not limited to, at least one of a silicon oxide layer, a silicon oxynitride layer, or a high-k dielectric layer. The storage layer 18 may include, but is not limited to, at least one of a silicon nitride layer, a silicon oxynitride layer, or a silicon layer. The tunneling layer 19 may include, but is not limited to, at least one of a silicon oxide layer or a silicon oxynitride layer.

In step S8-2, a channel layer 16 may be formed on the storage stacked layer surface by at least one of chemical vapor deposition (CVD), physical vapor deposition (PVD), or atomic layer deposition (ALD). The channel layer 16 may include, but is not limited to, at least one of a polysilicon layer, a single crystal silicon layer, or an amorphous silicon layer.

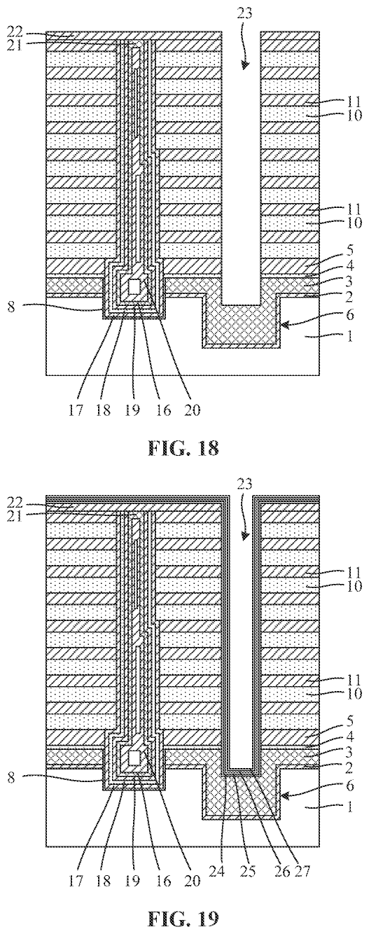

For example, the filler material 20 (silicon oxide or other dielectric material) may be further deposited in the remaining space of the channel hole to completely or partially fill the channel hole. A semiconductor contact 21 may be further formed on an upper portion of the channel hole. A material of the semiconductor contact 21 may include, but is not limited to, polysilicon and may connect to the channel layer 16. To protect the vertical channel structure, as illustrated in FIG. 18, a cover layer 22 (e.g., a silicon oxide layer) may be further deposited on the stacked structure to cover the channel structure.

The method may further include the following steps.

Referring to FIG. 18, a gate line slit 23 may be formed using a wet etching process and/or a dry etching process, for example, DRIE. The gate line slit may penetrate vertically through the first stacked structure and extend at least down into the first sacrificial layer 3. In this embodiment, the gate line slit 23 may also penetrate through the cover layer 22 and the second stacked structure.

In some embodiments, since the substrate 1 is provided with the groove 6, the process window for forming the gate line slit 23 may be enlarged. A bottom of the gate line slit 23 may stay not only on the top surface of the substrate 1 but also below the top surface of the substrate 1.

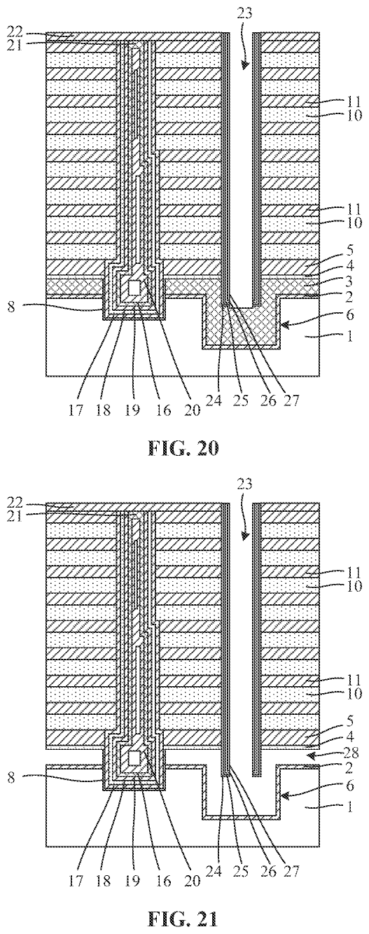

Referring to FIGS. 19-20, a side wall protective layer may be formed on a side wall of the gate line slit 23, so as to protect the side wall of the stacked structure exposed by the gate line slit from damage in a subsequent etching process.

In some embodiments, as illustrated in FIG. 19, the side wall protective layer may be first deposited in the gate line slit and on the stacked structure. The side wall protective layer may be a multi-layer composite layer, so as not to be completely removed in subsequent multiple etching processes, and to continuously protect the side wall of the stacked structure. In this embodiment, the side wall protection layer may include a first silicon nitride layer 24, a silicon oxide layer 25, a second silicon nitride layer 26, and an aluminum oxide layer 27 sequentially from outside to inside in a radial direction of the gate line slit. Of course, in other embodiments, the composition of the side wall protective layer may be adjusted as desired, and the protection scope of the present disclosure is not to be unduly limited herein.

As illustrated in FIG. 20, a portion of the side wall protective layer located at the bottom of the gate line slit 23 may be removed to expose at least a portion of the first sacrificial layer 3, and a portion of the side wall protective layer located on the stacked structure may be removed.

Referring to FIG. 21, the first sacrificial layer 3 may be removed by using a wet etching process and/or a dry etching process to obtain a bottom lateral slit 28.

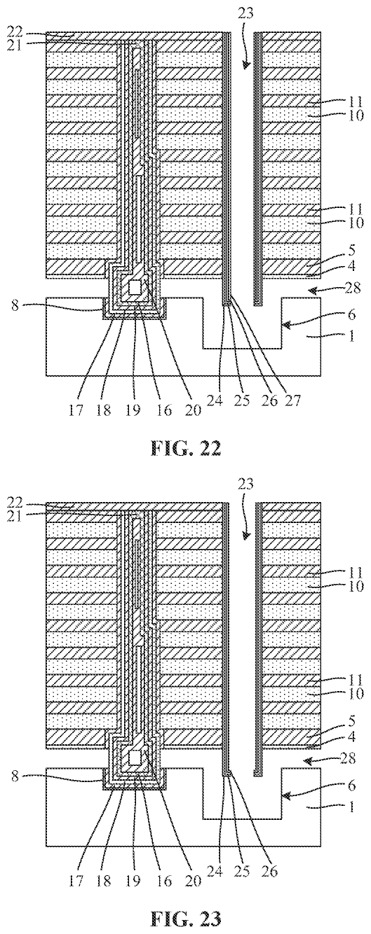

Referring to FIGS. 22 to 24, a portion of the storage stacked layer may be removed via the bottom lateral slit 28 to expose a portion of the channel layer 16 and to remove the first protective layer 2 and the second protective layer 4.

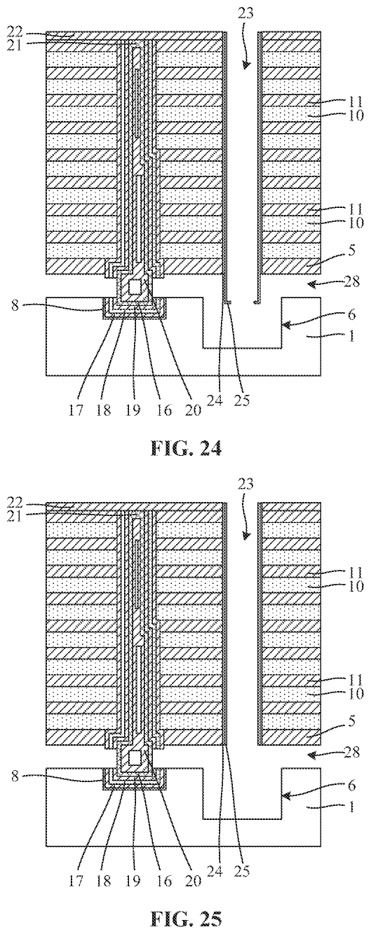

For example, as illustrated in FIG. 22, the barrier layer 17 in the storage stacked layer may be first removed along a side wall of the bottom lateral slit 28. The third protection layer 8 and the first protection layer 2 may be removed simultaneously. Then, the aluminum oxide layer 27 in the side wall protection layer may be removed, as illustrated in FIG. 23. Then the storage layer 18 and the tunneling layer 19 (as illustrated in FIG. 11) in the exposed storage stacked layer may be removed as illustrated in FIG. 24. Meanwhile, the second protection layer 4, a portion of the first silicon nitride layer 24 in the side wall protection layer below the bottom dielectric layer 5 and the second silicon nitride layer 26 may be also removed.

Referring to FIG. 25, a surface of the bottom lateral slit 28 may be pre-cleaned, during which a portion of the side wall protection layer protruding into the bottom lateral slit is removed.

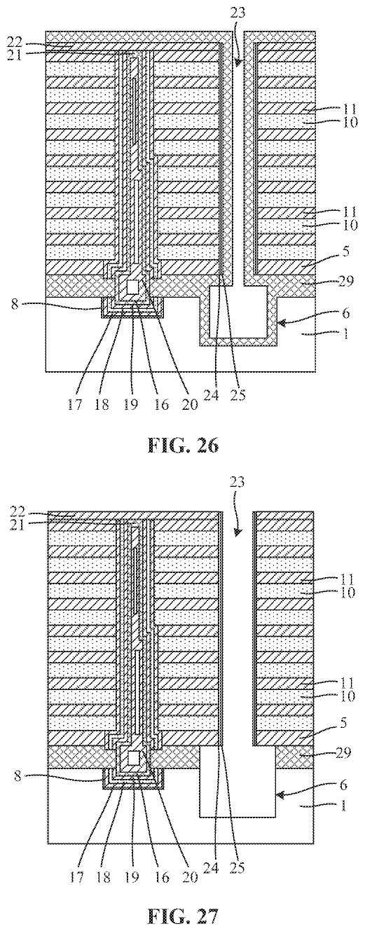

Referring to FIGS. 26 and 27, a bottom polysilicon layer 29 may be deposited in the bottom lateral slit 28 by chemical vapor deposition (CVD), physical vapor deposition (PVD), atomic layer deposition (ALD), or other suitable processes. In this process, a polysilicon material may be deposited on the side wall of the gate line slit 23 and the cover layer 22 (as illustrated in FIG. 26). Then, the polysilicon material on the side walls of the gate line slit 23 and on the cover layer 22 may be removed (as illustrated in FIG. 27) through etchback.

For example, if the groove 6 is formed in the substrate 1, the polysilicon material on the side wall and the bottom surface of the groove 6 may be removed at the same time in the above-described etchback.

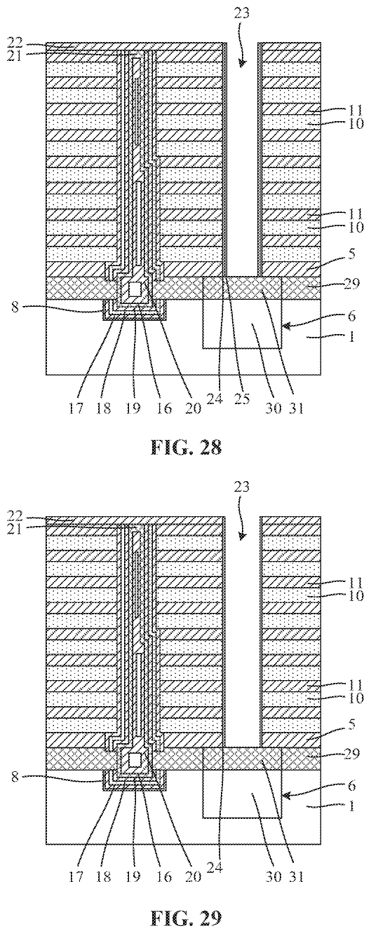

For example, referring to FIG. 28, a bottom epitaxial layer may be further formed in the groove 6. In this embodiment, the bottom epitaxial layer may include an N-type epitaxial silicon layer 30 and an N-type polysilicon layer 31 sequentially from bottom to top.

Referring to FIG. 29, a silicon oxide layer 25 on the side wall protective layer may further be removed.

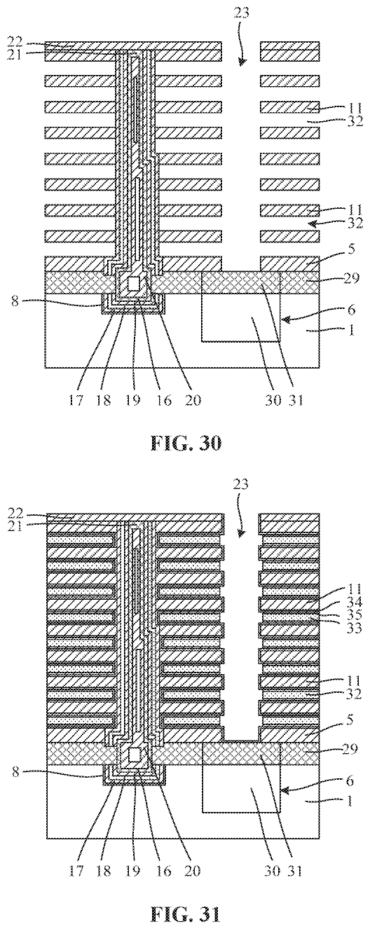

Referring to FIG. 30, a gate sacrificial layer may be removed using a wet etching process and/or a dry etching process to obtain a plurality of gate lateral slits 32.

Referring to FIG. 31, a conductive layer may be formed in the gate lateral slit 32.

In some embodiments, an adhesive layer and a gate material layer 33 may be sequentially deposited in the gate lateral slit 32 as the conductive layer using chemical vapor deposition (CVD), physical vapor deposition (PVD), atomic layer deposition (ALD), or other suitable processes. The adhesive layer may include, but is not limited to, at least one of a high-k dielectric material layer (e.g., aluminum oxide), a TiN layer, a Ti layer, a Ta layer, or a TaN layer. The gate material layer may include, but is not limited to, a tungsten layer. In this embodiment, the adhesive layer may be made of an aluminum oxide layer 34 and a titanium nitride layer 35.

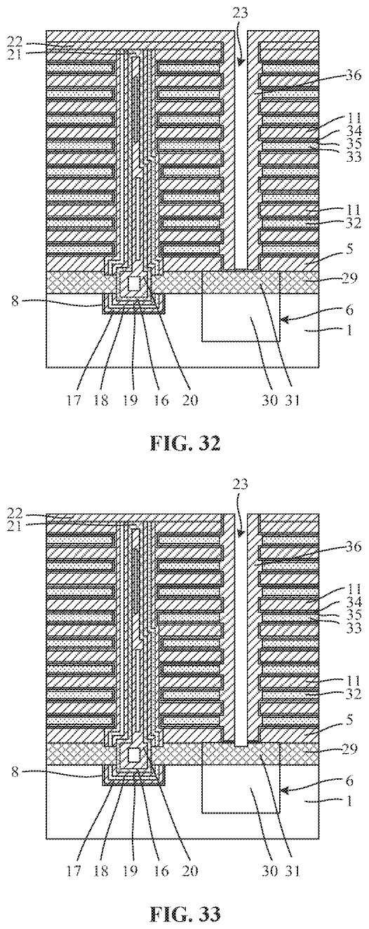

Referring to FIGS. 32 to 34, an array common source structure may be formed in the gate line slit 23.

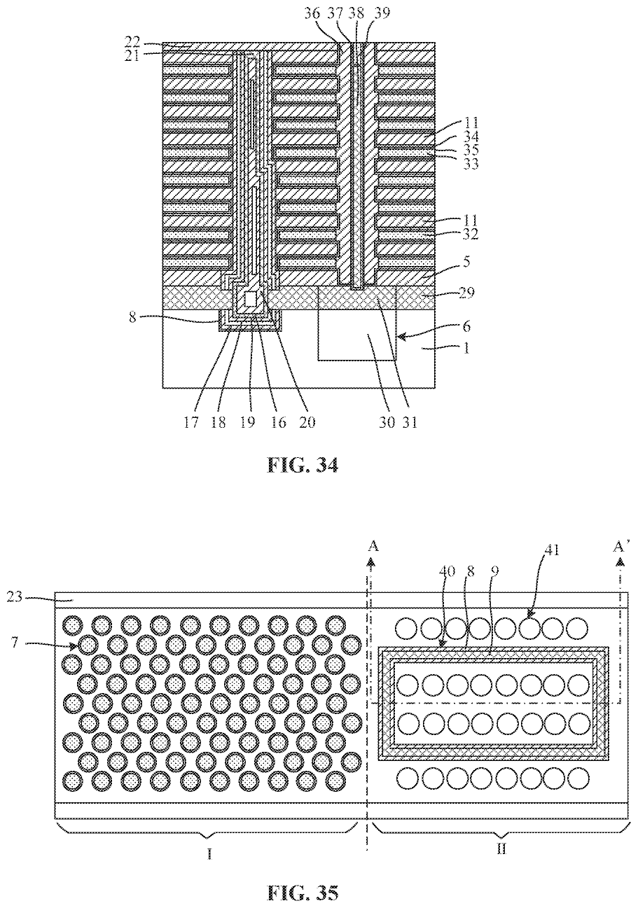

For example, as illustrated in FIG. 32, an isolated side wall 36 may be formed on the side wall of the gate line slit 23. Then a portion of the isolated side wall 36 on the cover layer 22 may be removed as illustrated in FIG. 33. A portion of the isolated side wall 36 and the alumina layer 34 on the middle of the bottom of the gate line slit 23 may be removed to expose the bottom polysilicon layer 29 (or the bottom epitaxial layer). Then a conductive portion of the array common source structure may be formed as illustrated in FIG. 34. For example, the conductive portion of the array common source structure may include a titanium nitride layer 37, a dielectric layer 38 (e.g., polysilicon) wrapped in the titanium nitride layer 37, and a tungsten layer 39 positioned above the dielectric layer 38. The bottom and side walls of the tungsten layer 39 may be wrapped with the titanium nitride layer 37 to prevent diffusion of tungsten.

In this way, a three-dimensional memory may be manufactured. In the forming method of the three-dimensional memory according to the present embodiment, the bottom of the channel hole may be etched to form the lower part of the channel hole, the side wall of the first sacrificial layer may be oxidized, the channel hole may be filled with the second sacrificial layer, the stacked structure may be formed, and the upper part of the channel hole may be formed. On the one hand, the lower part of the larger channel hole having a larger size may improve the supporting capability of the core region and the dummy region after the removal of the bottom sacrificial layer. On the other hand, the bottom deformation of the channel hole in the core region may be reduced, and the distribution of the holes may be more uniform.

### Second Embodiment

The present embodiment adopts substantially the same technical solution as the first embodiment, except that the present embodiment further includes a step of forming an annular groove in a step region of a three-dimensional memory before forming a first stacked structure.

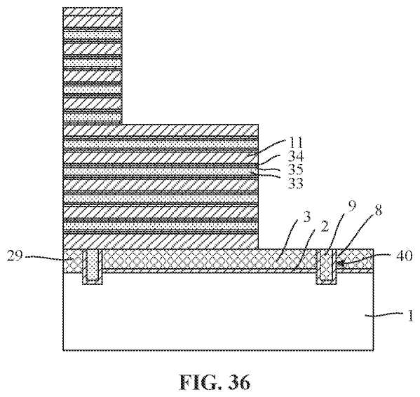

Referring to FIGS. 35 and 36, FIG. 35 is a plane layout of the three-dimensional memory, and FIG. 36 is a cross-sectional diagram of the three-dimensional memory along the A-A′ direction.

In some embodiments, the three-dimensional memory may be divided into a core region I and a step region II. In this embodiment, before forming the first stacked structure, the method may further include a step of forming an annular groove 40 in the step region II. In the step of forming a third protective layer 8, the third protective layer 8 may be further formed on a side wall of a first sacrificial layer 3 exposed by the annular groove 40. In the step of forming a second sacrificial layer 9 in a first channel hole 7, the second sacrificial layer 9 may further be formed in the annular groove 40. In the step of removing a first sacrificial layer 3 to obtain a bottom lateral slit, a portion of the first sacrificial layer 3 surrounded by the annular groove 40 may be not removed.

For example, the annular groove 40 may be polygonal, circular, elliptical, or other suitable shapes.

For example, the method may further include a step of forming a plurality of dummy channel holes 41 in the step region II.

For example, at least one of the dummy channel holes may be located within a surrounding area of the annular groove 40 and/or outside the surrounding area of the annular groove 40.

The forming method of the three-dimensional memory of the present embodiment may further form the annular groove in the dummy region (located in the step region) when performing bottom etching, so that an intermediate region surrounded by the annular groove is prevented from being removed when the bottom sacrificial layer is removed, thereby greatly improving the support capability of the core region and the dummy region when the bottom sacrificial layer is removed.

### Third Embodiment

In this embodiment, a three-dimensional memory is provided. Referring to FIG. 34, a cross-sectional diagram of the three-dimensional memory is illustrated. The three-dimensional memory may include a substrate 1, a bottom poly silicon layer 29, a bottom dielectric layer 5, a plurality of conductive layers, a channel structure, and an array common source structure. The bottom polysilicon layer 29 may be on the substrate 1. The plurality of the conductive layers may be stacked on the bottom dielectric layer 5. A dielectric layer 11 may be disposed between adjacent conductive layers. The channel structure may extend through the plurality of the conductive layers and dielectric layers 11 and extend down into the substrate 1. The channel structure may include a channel layer 16 and a storage stacked layer surrounding an outer side surface and an outer bottom surface of the channel layer. The bottom polysilicon layer 29 may extend laterally through the storage stacked layer to be connected to the channel layer 16. A width of a portion of the channel structure in the bottom dielectric layer 5, the bottom polysilicon layer 29, and the substrate 1 may be larger than a width of a portion of the channel structure in the conductive layer. The array common source structure may penetrate through the plurality of the conductive layers, the plurality of the dielectric layers 11, and the bottom dielectric layer 5.

For example, a portion of the channel structure in the plurality of the conductive and dielectric layers may be divided into at least two segments, wherein a width of an upper segment of the channel structure is less than a width of a lower segment.

For example, the substrate 1 may include, but is not limited to, a Si substrate, a Ge substrate, a Silicon On Insulator (SOI) substrate, a Germanium On Insulator (GOI) substrate, or the like. The substrate 1 may be P-type doped or N-type doped.

For example, the dielectric layer 11 may include, but is not limited to, a silicon oxide layer. The conductive layer may include an adhesion layer and a gate material layer 33. The conductive layer may include, but is not limited to, at least one of a high-k dielectric material layer (e.g., aluminum oxide), a TiN layer, a Ti layer, a Ta layer, or a TaN layer. The gate material layer 33 may include, but is not limited to, a tungsten layer. In this embodiment, the adhesive layer may be made of aluminum oxide layer 34 and titanium nitride layer 35.

For example, the storage stacked layer may include a barrier layer 17, a storage layer 18, and a tunneling layer 19 in the radial direction of the channel hole sequentially from outside to inside in a radial direction of the channel hole. The barrier layer 17 may include, but is not limited to, at least one of a silicon oxide layer, a silicon oxynitride layer, or a high k dielectric layer. The storage layer 18 may include, but is not limited to, at least one of a silicon nitride layer, a silicon oxynitride layer, or a silicon layer. The tunneling layer 19 may include, but is not limited to, at least one of a silicon oxide layer or a silicon oxynitride layer. The channel layer 16 may include, but is not limited to, at least one of a polysilicon layer, a single crystalline silicon layer, or an amorphous silicon layer.

For example, please refer to FIGS. 35 and 36, wherein FIG. 35 is a plane layout of the three-dimensional memory, and FIG. 36 is a cross-sectional diagram of the three-dimensional memory along the A-A′ direction.

In some embodiments, the three-dimensional memory may include a core region I and a step region II. In this embodiment, the step region II array be provided with an annular groove structure.

In some embodiments, the annular groove structure may include an annular groove 40. A third protective layer 8 may be provided on an inner wall of the annular groove 40. The annular groove may be filled with a second sacrificial layer 9.

For example, the annular groove 40 may be polygonal, circular, elliptical, or other suitable shape.

For example, the step region II may be provided with a plurality of dummy channel hole structures including a dummy channel hole 41 and dielectric filled in the dummy channel hole 41.

For example, at least one of the dummy channel hole structures may be located within a surrounding area of the annular channel structure and/or outside the surrounding area of the annular channel structure.

In the three-dimensional memory of the present embodiment, both upper and lower parts of the channel hole have high distribution uniformity, and the filling of the bottom polysilicon layer has high uniformity. The annular groove structure of the step region helps to improve the structural stability of the device.

To sum up, the three-dimensional memory of the present disclosure and the forming method thereof may perform bottom etching at the channel hole position to form the lower part of the channel hole, oxidize the side wall of the first sacrificial layer, fill the second sacrificial layer in the hole, form the stacked structure, and form the upper part of the channel hole. On the one hand, the lower part of the larger channel hole having a larger size can improve the support capability of a core region and a dummy region after the bottom sacrificial layer is removed. On the other hand, the lower part of the channel hole having a larger size may reduce deformation of a bottom of the channel hole in the core region, and make a distribution of the holes more uniform, which is conducive to improving a filling process window after the removal of the bottom sacrificial layer, and may directly form a silicon gouging with a relatively deep bottom, so as to avoid a key dimension enlargement of the top of the channel hole during the formation of the silicon gouging after the etching. In addition, the dummy region may be further annular groove when the bottom is etched, which prevents an intermediate region surrounded by the annular groove from being removed when the bottom sacrificial layer is removed, thereby greatly improving the support capacity of the core region and the dummy region when the bottom sacrificial layer is removed. Therefore, the present disclosure effectively overcomes disadvantages of the related art and has a high industrial utilization value.

The above-described embodiments are merely illustrative and not limiting the embodiment. For those skilled in the art, other different forms of changes or variations may be made on the basis of the above description. All embodiments need not and cannot be exhaustive here. The obvious variations or modifications derived therefrom are still within the scope of protection created by the present disclosure.

1. A method for forming a three-dimensional memory, comprising:
providing a base structure comprising a first protective layer, a first sacrificial layer, a second protective layer, and a bottom dielectric layer sequentially from bottom to top;
forming a first channel hole in the base structure, the first channel hole penetrating through the bottom dielectric layer, the second protective layer, the first sacrificial layer, and the first protective layer;
forming a third protective layer on a side wall of the first sacrificial layer, wherein the side wall of the first sacrificial layer is exposed by the first channel hole;
forming a second sacrificial layer in the first channel hole;
forming a first stacked structure on the bottom dielectric layer, the first stacked structure comprising gate sacrificial layers and dielectric layers, wherein the gate sacrificial layers and dielectric layers are alternately stacked;
forming a second channel hole in the first stacked structure, the second channel hole penetrating vertically through the first stacked structure, and an orthographic projection of the second channel hole onto the bottom dielectric layer being located within the first channel hole;
removing the second sacrificial layer; and
forming a channel structure in the first channel hole and the second channel hole, the channel structure including a channel layer and a storage stacked layer surrounding an outer side surface and an outer bottom surface of the channel layer, wherein a size of a bottom of the channel structure along a horizontal direction is greater than a size of a portion of the channel structure in the first stacked structure.

2. The method for forming the three-dimensional memory of claim 1, wherein after forming the second channel hole and before removing the second sacrificial layer, the method further comprises:
forming a third sacrificial layer in the second channel hole;
forming a second stacked structure on the first stacked structure, the second stacked structure including other gate sacrificial layers and dielectric layers, wherein the gate sacrificial layers and dielectric layers are alternately stacked;
forming a third channel hole in the second stacked structure, the third channel hole penetrating vertically through the second stacked structure, and an orthographic projection of the third channel hole onto the first stacked structure being located within the second channel hole;
removing the third sacrificial layer; and
forming the channel structure in the third channel hole after removing the third sacrificial layer and the second sacrificial layer.

3. The method for forming the three-dimensional memory of claim 1, further comprising:
forming a gate line slit, the gate line slit penetrating vertically through the first stacked structure and extending at least down into the first sacrificial layer;
forming a side wall protective layer on a side wall of the gate line slit;
removing the first sacrificial layer to obtain a bottom lateral slit;
removing a portion of the storage stacked layer via the bottom lateral slit to expose a portion of the channel layer and removing the first protective layer and the second protective layer;
forming a bottom polysilicon layer in the bottom lateral slit;
removing the gate sacrificial layers to obtain a plurality of gate lateral slits;
forming a conductive layer in the gate lateral slits; and
forming an array common source structure in the gate line slit.

4. The method for forming the three-dimensional memory of claim 3, wherein providing the base structure comprises:
providing a substrate with a groove, wherein the first protective layer is located between the substrate and the first sacrificial layer; and
filling the groove with the first protective layer and the first sacrificial layer, wherein an orthographic projection of the gate line slit onto the substrate is located within the groove.

5. The method for forming the three-dimensional memory of claim 4, further comprising: forming a bottom epitaxial layer in the groove after forming the bottom polysilicon layer and before removing the gate sacrificial layer.

6. The method for forming the three-dimensional memory of claim 5, wherein forming the bottom epitaxial layer comprises forming an N-type epitaxial silicon layer and an N-type polysilicon layer sequentially from bottom to top.

7. The method for forming the three-dimensional memory of claim 3, wherein the three-dimensional memory comprises a step region, and the method further comprises forming an annular groove in the step region before forming the first stacked structure, the annular groove penetrates vertically through the first sacrificial layer and the first protective layer, wherein
forming the third protective layer comprises further forming the third protective layer on a side wall of the first sacrificial layer, wherein the side wall of the first sacrificial layer is exposed by the annular groove;
forming the second sacrificial layer in the first channel hole comprises further forming the second sacrificial layer in the annular groove; and
removing the first sacrificial layer to obtain the bottom lateral slit comprises not removing a portion of the first sacrificial layer surrounded by the annular groove.

8. The method for forming the three-dimensional memory of claim 7, wherein forming the annular groove comprises forming the annular groove in a shape of a polygonal ring, a circular ring, or an elliptical ring.

9. The method for forming the three-dimensional memory of claim 7, wherein the method further comprises forming a plurality of dummy channel holes in the step region.

10. The method for forming the three-dimensional memory of claim 9, wherein
forming the plurality of dummy channel holes comprises forming at least one of the dummy channel holes within a surrounding area of the annular groove or outside the surrounding area of the annular groove.

11. A three-dimensional memory comprising:
a bottom polysilicon layer;
a bottom dielectric layer on the bottom polysilicon layer;
a plurality of conductive layers stacked above the bottom dielectric layer, wherein a dielectric layer is disposed between adjacent conductive layers; and
a channel structure penetrating vertically through the plurality of conductive layers and the dielectric layer and extending down through the bottom polysilicon layer, the channel structure including a channel layer and a storage stacked layer surrounding an outer side surface and an outer bottom surface of the channel layer, the bottom polysilicon layer extending laterally through the storage stacked layer to connect the channel layer;
wherein a size of a bottom of the channel structure in a horizontal direction is greater than a size of a portion of the channel structure in the plurality of conductive layers.

12. The three-dimensional memory of claim 11, wherein the bottom of the channel structure comprises:
a portion of the channel structure located in the bottom dielectric layer; and
a portion of the channel structure in a substrate, wherein the bottom polysilicon layer is located between the substrate and the bottom dielectric layer.

13. The three-dimensional memory of claim 11, wherein the portion of the channel structure in the plurality of conductive layers is divided into at least two segments, wherein a width of an upper segment of the channel structure is less than a width of a lower segment of the channel structure.

14. The three-dimensional memory of claim 11, wherein the three-dimensional memory comprises:
a substrate, wherein the bottom polysilicon layer is located between the substrate and the bottom dielectric layer; and
a step region comprising an annular groove structure, the annular groove structure penetrating vertically through the bottom polysilicon layer and extending down into the substrate.

15. The three-dimensional memory of claim 14, wherein the annular groove structure is in a shape of a polygonal ring, a circular ring, or an elliptical ring.

16. The three-dimensional memory of claim 14, wherein the step region comprises a plurality of dummy channel hole structures.

17. The three-dimensional memory of claim 16, wherein
at least one of the plurality of dummy channel hole structures is located within a surrounding area of the annular groove structure; or
at least one of the plurality of dummy channel hole structures is located outside the surrounding area of the annular groove structure.

18. A three-dimensional memory comprising:
a bottom polysilicon layer;
a bottom dielectric layer located on the bottom polysilicon layer;
a plurality of conductive layers stacked above the bottom dielectric layer, and a dielectric layer is disposed between adjacent conductive layers; and
a channel structure penetrating vertically through the plurality of conductive layers and the dielectric layer and extending down through the bottom polysilicon layer, the channel structure including a channel layer and a storage stacked layer surrounding an outer side surface and an outer bottom surface of the channel layer, the bottom polysilicon layer extending laterally across the storage stacked layer to connect the channel layer,
wherein the channel structure comprises a protruding portion.

19. The three-dimensional memory of claim 18, wherein the protruding portion is located in the bottom dielectric layer, the bottom polysilicon layer, and a substrate, wherein the bottom polysilicon layer is located between the substrate and the bottom dielectric layer.

20. The three-dimensional memory of claim 18, wherein a portion of the channel structure in the plurality of the conductive layers and the dielectric layer is divided into at least two segments, wherein a width of an upper segment of the channel structure is less than a width of a lower segment of the channel structure.
